(19) United States
(12) Patent Application Publication
(10) Pub. No.: US 2007/0141749 A1
(43) Pub. Date: Jun. 21, 2007

(54) Die attachment method for LED chip and structure thereof

(76) Inventors: Yi-Fong Lin, Lung Tan (TW); Shyi-Ming Pan, Lung Tan (TW); Way-Jze Wen, Lung Tan (TW); Fen-Ren Chen, Lung Tan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/311,243

(22) Filed: Dec. 20, 2005

(51) Int. Cl. H01L 21/00

(52) U.S. Cl. 438/108; 438/118; 257/E23.04

(57) ABSTRACT

A die attachment method for LED chips and the structure thereof are disclosed. While attaching a LED chip to a substrate, surface of two bonding material is ionized by ultrasonic waves so as to make the attachment of a LED chip to a substrate is under low temperature operating condition and having better heat dissipation structure.

### BACKGROUND OF THE INVENTION

The present invention relates to a light emitting diode, especially to a die attachment method for LED chips and the structure thereof.

Conventional way of manufacturing LED is attaching LED chips on a substrate by silver conductive adhesive. According to various types of LED, the substrate can be lead-frame, PCB (printed circuit board), PLCC (plastic leaded chip carrier), LTCC (low temperature co-fired ceramic) or FR4 (flame retardant type 4). Then the chip attached on the substrate by silver conductive adhesive is heated at 150 degrees Celsius for one and a half hours.

Refer to FIG. 1, a schematic drawing showing the conventional die attachment structure for LED is disclosed. A LED chip 10′ is mounted on the substrate 30′ by silver conductive adhesive 20′, as disclosed in Taiwanese patent publication No. 433553-LED package and heat dissipation structure. Refer to Taiwanese patent publication No. 463394-chip-type LED and manufacturing method thereof, the chip is connected to the substrate by means of silver paste, so does the Taiwanese patent publication No. 290733, surface mounting LED and the manufacturing method thereof, the semiconductor chip is mounted by silver paste. Moreover, Taiwanese patent publication No. 541731, LED package/module, the LED chip is also fixed on the substrate by silver paste. However, the LED devices use paste as adhesive for die attachment always get problem of changes in position of LED chips caused by improper adhesive dispensation. Moreover, the thermal conductivity of the paste is poor.

Furthermore, the LED chip is attached on the substrate by bonding material. Refer to FIG. 2, the LED chip 10′ is connected on the substrate 20′ by a solder ball. For example, refer to Taiwanese patent No. 232600-LED packaging, a packaging method for attaching LED chips is disclosed. The method comprises the steps of: weld a LED chip on a substrate at least so as to form a circuit and then package the LED chip by application of packaging material. Also refer to Taiwanese patent publication No. 533750, LED lights, the LED parts are disposed on the circuit board by automatic soldering. However, operating temperature of bonding is higher than 210 degrees Celsius so that the LED structure is damaged. Therefore, the defective rate produced by a manufacturing process is increased.

In order to solve the above problems of die attachment of LED chip such as paste with poor conductivity, changes in positions of LED chips caused by inadequate adhesive disposition, or high temperature soldering that may damage LED chip, the present invention provides a method that attaches chips in low temperature and the LED structure with good thermal conductivity.

### SUMMARY OF THE INVENTION

Therefore it is a primary object of the present invention to provide a die attachment method for LED chips and structure thereof. First, a first bonding layer is disposed on one side of a light-emitting diode chip while a second bonding layer is arranged on one side of a substrate. Then surfaces of the first bonding layer and the second bonding layer are ionized by ultrasonic waves under low temperature so as to finish die attachment process of LED chips.

It is another object of the present invention to provide a die attachment method for LED chips and structure thereof. By use of two bonding material, the die attachment structure has better heat dissipation effect.

In order to achieve above objects, the present invention uses ultrasonic waves to ionize surface of two bonding material while a LED chip is attached to a substrate so as to make the attachment of the LED chip to the substrate under low temperature operating condition and the LED devices have better thermal conductivity structure.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing showing die attachment structure of LED chip produced by conventional technology;

FIG. 2 is a schematic drawing showing a LED chip attached to a substrate with bonding material therebetween by conventional technology;

FIG. 3 is a manufacturing flow chart of an embodiment in accordance with the present invention;

FIG. 4 is a schematic drawing showing part of the structure of an embodiment in accordance with the present invention;

FIG. 5 is a schematic drawing showing part of the structure of an embodiment in accordance with the present invention;

FIG. 6 is a schematic drawing showing structure of an embodiment in accordance with the present invention;

FIG. 7 is a schematic drawing showing structure of an embodiment in accordance with the present invention.

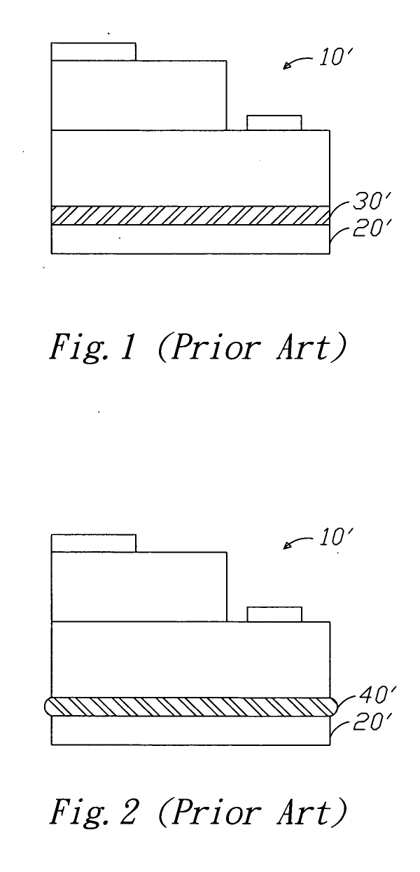

### DETAILED DESCRIPTION OF THE PREFERRED EMBODIMENT

Conventional technology for attaching LED chips to substrates is by means of silver paste or bonding material. However, the silver paste may cause problems of poor thermo performance as well as changes in positions of LED chips while the bonding material has disadvantage of damaged LED chips caused by high temperature (over 200 degrees Celsius) during bonding process. Thus the present invention provides a manufacturing method under low temperature condition and a structure with high thermal conductivity.

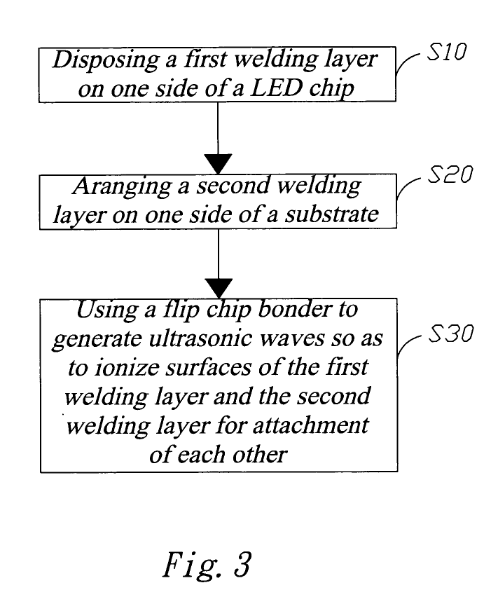

Refer to FIG. 3, a die attachment method of LED chips in accordance with the present invention includes the steps of: step S10, a first bonding layer is disposed on one side of a LED chip; step S20, a second bonding layer is arranged on one side of a substrate; step S30 ionize surfaces of the first bonding layer and the second bonding layer so as to connect the first bonding layer with the second bonding layer.

During step S30, a flip chip bonder is used to generate ultrasonic waves so as to ionize surfaces of the first bonding layer and the second bonding layer for attachment of each other. The LED chips won't get damage because the attachment by means of ultrasonic waves is processed under temperature lower than 150 degrees Celsius.

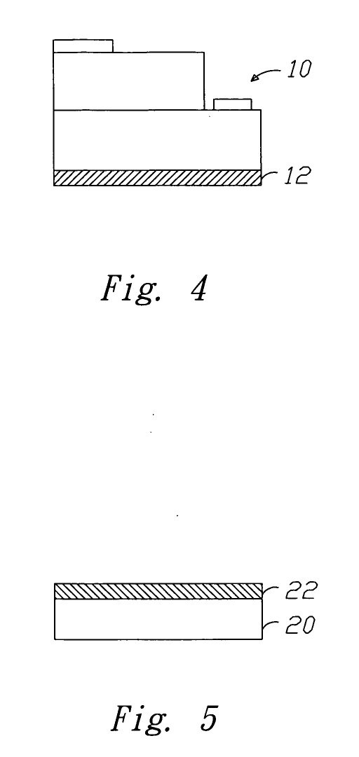

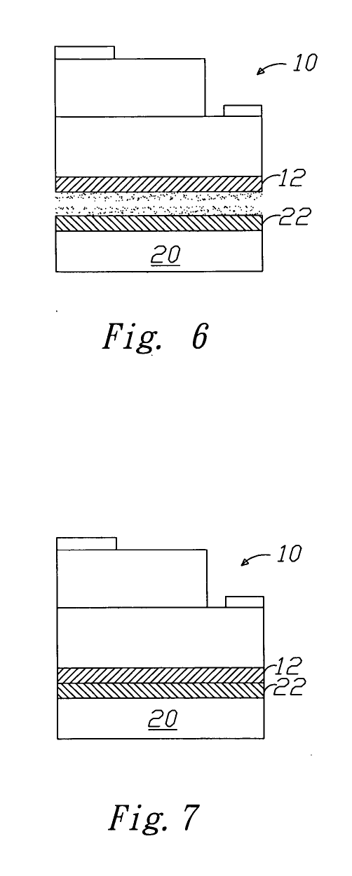

Refer from FIG. 4 to FIG. 7, the present invention provides a LED chip 10 disposed with a first bonding layer 12 on one side thereof, as shown in FIG. 4. Refer to FIG. 5, a second bonding layer 22 is arranged on one side of a substrate 20. Then surfaces of the first bonding layer 12 and the second bonding layer 22 are ionized by ultrasonic waves, as shown in FIG. 6. Finally, refer to FIG. 7, the first bonding layer 12 and the second bonding layer 22 are connected with each other.

The LED chip 10 is a chip made by gallium nitride-based III-V group compound semiconductor. The substrate 20 is selected from one of the following types—lead-frame, PCB, PLCC, LTCC and FR4 and is made by one of the high thermal conductivity material such as aluminum nitride (AlN), silicon, copper (Cu), aluminum (Al) and ceramic. The first bonding layer or the second bonding layer is selected from one of gold-tin (AuSn), gold (Au), gold-indium (InAu), tin (Sn) and tin-lead (SnPb).

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A die attachment method for LED chip comprising the steps of:
disposing a first bonding layer on one side of a light-emitting diode chip;
arranging a second bonding layer on one side of a substrate; and
ionizing surfaces of the first bonding layer and the second bonding layer by means of ultrasonic waves so as to connect the first bonding layer to the second bonding layer.

2. The method as claimed in claim 1, wherein the ultrasonic waves are generated by a flip chip bonder.

3. The method as claimed in claim 1, wherein in step of connecting the first bonding layer to the second bonding layer, operating temperature is lower than 150 degrees Celsius.

4. A die attachment structure of light-emitting diode chip comprising
a light-emitting diode chip;
a first bonding layer arranged on one side of the light-emitting diode chip;
a second bonding layer connected to one side of the first bonding layer; and
a substrate connected to one side of the second bonding layer;
wherein the first bonding layer and the second bonding layer are connected to each other by means of ultrasonic waves.

5. The structure as claimed in claim 4, wherein the light-emitting diode chip is a gallium nitride-based III-V group compound semiconductor chip.

6. The structure as claimed in claim 4, wherein the first bonding layer is selected from one of gold-tin (AuSn), gold (Au), gold-indium (InAu), tin (Sn) and tin-lead (SnPb).

7. The structure as claimed in claim 4, wherein the second bonding layer is selected from one of gold-tin (AuSn), gold (Au), gold-indium (InAu), tin (Sn) and tin-lead (SnPb).

8. The structure as claimed in claim 4, wherein the substrate is made by high thermal conductivity material.

9. The structure as claimed in claim 4, wherein the material of the substrate is selected from one of aluminum nitride (AlN), silicon, copper (Cu), aluminum (Al) and ceramic.

10. The structure as claimed in claim 4, wherein the substrate is lead-frame, printed circuit board (PCB), plastic leaded chip carrier (PLCC), low temperature co-fired ceramic (LTCC) or flame retardant type 4 (FR4).
